(19) United States
(12) Patent Application Publication
(10) Pub. No.: US 2015/0007889 A1
(43) Pub. Date: Jan. 8, 2015

(54) PRESSURE-SENSITIVE ADHESIVE SHEET, PROTECTION UNIT, AND SOLAR CELL MODULE

(71) Applicant: NITTO DENKO CORPORATION, Osaka (JP)

(72) Inventors: Yasushi Buzoujima, Osaka (JP); Noriaki Fukushima, Osaka (JP); Michiharu Yamamoto, Osaka (JP); Hongxi Zhang, Temecula, CA (US)

(21) Appl. No.: 14/375,347

(22) PCT Filed: Feb. 6, 2013
(86) PCT No.: PCT/JP2013/052674

§ 371 Date: Jul. 29, 2014

(30) Foreign Application Priority Data
Feb. 6, 2012 (JP) 2012-023395

(51) Int. Cl. H01L 31/048; C09J 7/02; H01L 31/055

(52) U.S. Cl. CPC H01L 31/048; H01L 31/055; C09J 7/026; C09J 2201/622; C09J 2203/322
USPC 136/259; 428/343

(57) ABSTRACT

A solar cell module includes a solar cell element, a protective member disposed at one side in a thickness direction of the solar cell element, a pressure-sensitive adhesive layer interposed between the solar cell element and the protective member and attached to the protective member, and a support layer formed on the other surface in the thickness direction of the pressure-sensitive adhesive layer and having an elastic modulus at 25° C. measured in a tensile test of 1 MPa to 9×10³ MPa.

### CROSS-REFERENCE TO RELATED APPLICATIONS

The present invention is a 35 U.S.C. 371 National Stage Entry of PCT/JP2013/052674, filed Feb. 6, 2013, which claims priority from Japanese Patent Application No. 2012-023395, filed on Feb. 6, 2012, the contents of which are herein incorporated by reference in their entirety.

### TECHNICAL FIELD

The present invention relates to a pressure-sensitive adhesive sheet, a protection unit, and a solar cell module, to be specific, to a solar cell module, a protection unit used in the solar cell module, and a pressure-sensitive adhesive sheet used in the solar cell module and the protection unit.

### BACKGROUND ART

It has been known that a solar cell module includes a solar cell element (cell) and a protective member that protects the solar cell element (cell) such as a glass layer.

It has been proposed that an antireflection (AR) treatment, an antiglare (AG) treatment, or the like is applied to a surface of the protective member so as to improve the light confinement efficiency and the light extraction efficiency of the solar cell module (ref: for example, the following Patent Document 1).

### PRIOR ART DOCUMENT

### Patent Document

Patent Document 1: Japanese Unexamined Patent Publication No. 2011-146529

### SUMMARY OF THE INVENTION

### Problems to be Solved by the Invention

There may be a case where the protective member is made of a glass layer and a plurality of the protective members are laminated and conveyed before being put into the solar cell module. In this case, there is a disadvantage that the mechanical strength of the glass layer is relatively low, so that the protective member is damaged by contact with another laminated glass layer.

It is an object of the present invention to provide a protection unit that is capable of effectively preventing damage to a protective member, a pressure-sensitive adhesive sheet that is used in the protection unit, and a solar cell module in which the protection unit and the pressure-sensitive adhesive sheet are used and having excellent reliability.

### Solution to the Problems

A solar cell module of the present invention includes a solar cell element, a protective member disposed at one side in a thickness direction of the solar cell element, a pressure-sensitive adhesive layer interposed between the solar cell element and the protective member and attached to the protective member, and a support layer formed on the other surface in the thickness direction of the pressure-sensitive adhesive layer and having an elastic modulus at 25° C. measured in a tensile test of 1 MPa to 9×10³ MPa.

In the solar cell module of the present invention, it is preferable that the support layer is an encapsulating layer that encapsulates the solar cell element and/or a substrate that is formed on the one surface in the thickness direction of the pressure-sensitive adhesive layer.

In the solar cell module of the present invention, it is preferable that the pressure-sensitive adhesive layer and/or the support layer contain(s) a wavelength conversion material.

In the solar cell module of the present invention, it is preferable that the wavelength conversion material is an organic dye.

A protection unit of the present invention includes a protective member, a pressure-sensitive adhesive layer, and a support layer used in the above-described solar cell module, wherein the protective member is disposed at one side in a thickness direction of a solar cell element, a pressure-sensitive adhesive member is interposed between the solar cell element and the protective member and is attached to the protective member, and the support layer is formed at the other surface in the thickness direction of the pressure-sensitive adhesive layer and has an elastic modulus at 25° C. measured in a tensile test of 1 MPa to 9×10³ MPa.

A pressure-sensitive adhesive sheet of the present invention includes a pressure-sensitive adhesive layer and a support layer used in the above-described solar cell module, wherein a pressure-sensitive adhesive member is interposed between a solar cell element and a protective member and is attached to the protective member and the support layer is formed at the other surface in a thickness direction of the pressure-sensitive adhesive layer and has an elastic modulus at 25° C. measured in a tensile test of 1 MPa to 9×10³ MPa.

In the pressure-sensitive adhesive sheet of the present invention, it is preferable that the pressure-sensitive adhesive layer contains a polymer and a wavelength conversion material.

In the pressure-sensitive adhesive sheet of the present invention, it is preferable that the mixing ratio of the wavelength conversion material with respect to 100 parts by mass of a pressure-sensitive adhesive is 0.001 to 3 parts by mass.

In the pressure-sensitive adhesive sheet of the present invention, it is preferable that the peel pressure-sensitive adhesive force at 180 degrees of the pressure-sensitive adhesive layer with respect to a stainless steel board at 25° C. is 0.1 N/20 mm to 100 N/20 mm.

### Effect of the Invention

In the protection unit in which the pressure-sensitive adhesive sheet of the present invention is used, the pressure-sensitive adhesive layer is attached to the protective member and the elastic modulus of the support layer that is formed on the other surface in the thickness direction of the pressure-sensitive adhesive layer is within a specific range, so that the mechanical strength of the protection unit is capable of being improved and thus, damage to the protective member is capable of being effectively prevented.

Furthermore, when a plurality of the protection units are laminated to be conveyed or stored, the above-described pressure-sensitive adhesive layer and support layer are capable of being interposed between a plurality of the laminated protective members, so that damage caused by contact of the protective members with themselves is capable of being prevented.

Thus, the solar cell module in which the above-described protection unit is used has excellent reliability.

### BRIEF DESCRIPTION OF THE DRAWINGS

FIG. 1 shows a sectional view of one embodiment of a pressure-sensitive adhesive sheet of the present invention.

FIG. 2 shows a sectional view of one embodiment of a protection unit of the present invention in which the pressure-sensitive adhesive sheet shown in FIG. 1 is used.

FIG. 3 shows a sectional view of a state in which a plurality of the protection units shown in FIG. 2 are laminated.

FIG. 4 shows a sectional view of a solar cell module in which the protection unit shown in FIG. 2 is used.

FIG. 5 shows process drawings for illustrating a method for producing the solar cell module shown in FIG. 4:

FIG. 5 (a) illustrating a step of preparing a protection unit,

FIG. 5 (b) illustrating a step of attaching solar cell elements to a back surface of a substrate,

FIG. 5 (c) illustrating a step of disposing an encapsulating layer,

FIG. 5 (d) illustrating a step of disposing a back sheet, and

FIG. 5 (e) illustrating a step of thermocompression bonding a laminate.

FIG. 6 shows a perspective view of the solar cell module in the middle of the production shown in FIG. 5 (b).

FIG. 7 shows a sectional view of another embodiment (an embodiment in which a support layer is made of a substrate and a first encapsulating layer) of a solar cell module of the present invention.

FIG. 8 shows process drawings for illustrating a method for producing the solar cell module shown in FIG. 7:

FIG. 8 (a) illustrating a step of preparing a protection unit,

FIG. 8 (b) illustrating a step of disposing a first encapsulating layer,

FIG. 8 (c) illustrating a step of attaching solar cell elements to a back surface of the first encapsulating layer,

FIG. 8 (d) illustrating a step of disposing a second encapsulating layer,

FIG. 8 (e) illustrating a step of disposing a back sheet, and

FIG. 8 (f) illustrating a step of thermocompression bonding a laminate.

FIG. 9 shows a sectional view of another embodiment (an embodiment in which a support layer is made of a first encapsulating layer) of a solar cell module of the present invention.

FIG. 10 shows process drawings for illustrating a method for producing the solar cell module shown in FIG. 9:

FIG. 10 (a) illustrating a step of preparing a protective member,

FIG. 10 (b) illustrating a step of attaching a pressure-sensitive adhesive layer,

FIG. 10 (c) illustrating a step of disposing a first encapsulating layer,

FIG. 10 (d) illustrating a step of attaching solar cell elements to a back surface of the first encapsulating layer,

FIG. 10 (e) illustrating a step of disposing a second encapsulating layer,

FIG. 10 (f) illustrating a step of disposing a back sheet, and

FIG. 10 (g) illustrating a step of thermocompression bonding a laminate.

### EMBODIMENT OF THE INVENTION

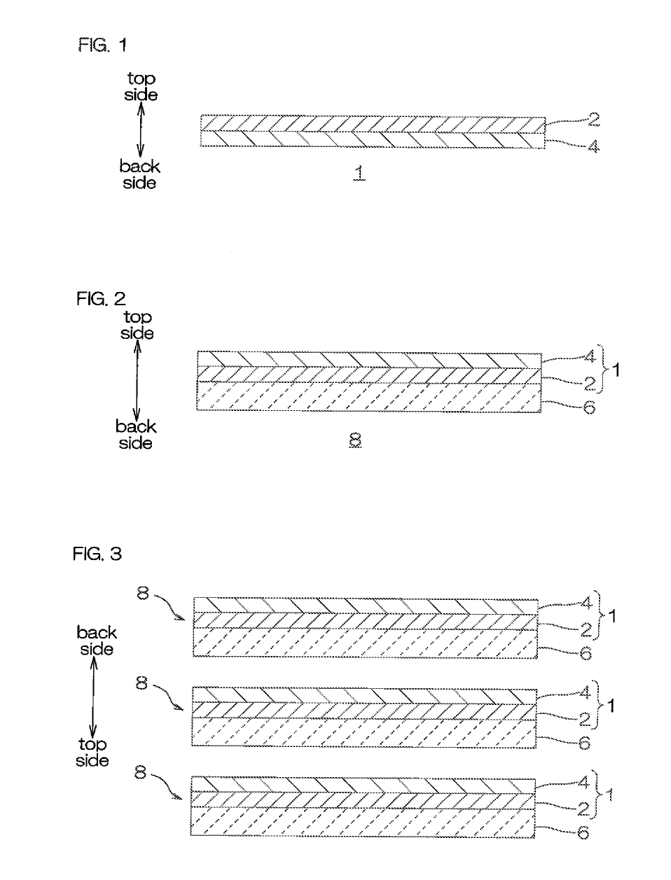

FIG. 1 shows a sectional view of one embodiment of a pressure-sensitive adhesive sheet of the present invention.

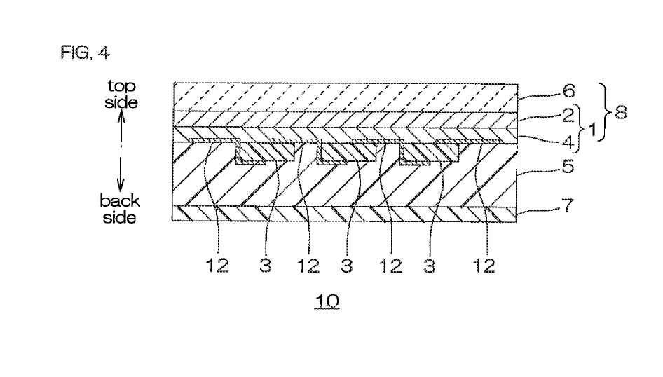

In FIG. 1, a pressure-sensitive adhesive sheet 1 is a pressure-sensitive adhesive sheet used in a protection unit 8 (ref: FIG. 2) to be described later and a solar cell module 10 (ref: FIG. 4) to be described later. The pressure-sensitive adhesive sheet 1 includes a pressure-sensitive adhesive layer 2 and, as a support layer, a substrate 4 that is laminated on a back surface (one surface in a thickness direction) of the pressure-sensitive adhesive layer 2.

The pressure-sensitive adhesive layer 2 is formed so as to correspond to the outer shape of the pressure-sensitive adhesive sheet 1.

The pressure-sensitive adhesive layer 2 contains a pressure-sensitive adhesive prepared from a polymer. Examples of the pressure-sensitive adhesive include an acrylic pressure-sensitive adhesive, a silicone pressure-sensitive adhesive, and a rubber pressure-sensitive adhesive and furthermore, a vinyl alkyl ether pressure-sensitive adhesive, a polyester pressure-sensitive adhesive, a polyamide pressure-sensitive adhesive, a urethane pressure-sensitive adhesive, a fluorine pressure-sensitive adhesive, and an epoxy pressure-sensitive adhesive.

The acrylic pressure-sensitive adhesive contains an acrylic polymer obtained by polymerization of a monomer component containing an alkyl(meth)acrylate as a main component.

The alkyl(meth)acrylate is a methacrylate and/or an acrylate. An example thereof includes an alkyl(meth)acrylate (a straight chain or branched chain alkyl having 1 to 20 carbon atoms) such as a methyl(meth)acrylate, an ethyl(meth)acrylate, a propyl(meth)acrylate, an isopropyl(meth)acrylate, an n-butyl(meth)acrylate, an isobutyl(meth)acrylate, an sec-butyl(meth)acrylate, a t-butyl(meth)acrylate, a pentyl(meth)acrylate, a neopentyl(meth)acrylate, an isoamyl(meth)acrylate, a hexyl(meth)acrylate, a heptyl(meth)acrylate, an octyl(meth)acrylate, a 2-ethylhexyl(meth)acrylate, an isooctyl(meth)acrylate, a nonyl(meth)acrylate, an isononyl(meth)acrylate, a decyl(meth)acrylate, an isodecyl(meth)acrylate, an undecyl(meth)acrylate, a dodecyl(meth)acrylate, a tridecyl(meth)acrylate, a tetradecyl(meth)acrylate, a pentadecyl(meth)acrylate, a hexadecyl(meth)acrylate, a heptadecyl(meth)acrylate, an octadecyl(meth)acrylate, a nonadecyl(meth)acrylate, and an eicosyl(meth)acrylate. These alkyl(meth)acrylates can be used alone or in combination of two or more.

The mixing ratio of the alkyl(meth)acrylate in the monomer component with respect to 100 parts by mass of the monomer component is, for example, 50 parts by mass or more, and is, for example, 100 parts by mass or less.

Also, in addition to the alkyl(meth)acylate, appropriately, a copolymerizable monomer that is copolymerizable with the alkyl(meth)acrylate is capable of being arbitrarily used as the monomer component in accordance with its purpose such as improvement of cohesive force, improvement of heat resistance, or the like.

Examples of the copolymerizable monomer include a carboxyl group-containing unsaturated monomer such as acrylic acid, methacrylic acid, carboxy ethyl acrylate, carboxy pentyl acrylate, itaconic acid, maleic acid, fumaric acid, and crotonic acid; an anhydride group-containing unsaturated monomer such as maleic anhydride and itaconic anhydride; a hydroxyl group-containing unsaturated monomer such as hydroxyethyl(meth)acrylate, hydroxypropyl(meth)acrylate, hydroxybutyl(meth)acrylate, hydroxyhexyl(meth)acrylate, hydroxyoctyl(meth)acrylate, hydroxydecyl(meth)acrylate, hydroxylauryl(meth)acrylate, and (4-hydroxymethyl cyclohexyl)methyl(meth)acrylate; a sulfonic acid group-containing unsaturated monomer such as styrenesulfonic acid, allylsulfonic acid, 2-(meth)acrylamide-2-methylpropane sulfonic acid, (meth)acrylamidepropane sulfonic acid, sulfopropyl(meth)acrylate, and (meth)acryloyloxynaphthalene sulfonic acid; an amide group-containing unsaturated monomer such as (meth)acrylamide, N,N-dimethyl(meth)acrylamide, N-butyl(meth)acrylamide, N-methylol(meth)acrylamide, and N-methylolpropane(meth)acrylamide; an alkylamino(meth)acrylate-based unsaturated monomer such as aminomethyl(meth)acrylate, aminoethyl(meth)acrylate, N,N-dimethylaminoethyl(meth)acrylate, and t-butylaminoethyl(meth)acrylate; an alkoxyl group-containing unsaturated monomer such as methoxyethyl(meth)acrylate and ethoxyethyl(meth)acrylate; a maleimide-based unsaturated monomer such as N-cyclohexylmaleimide, N-isopropylmaleimide, N-laurylmaleimide, and N-phenylmaleimide; an itaconimide-based unsaturated monomer such as N-methylitaconimide, N-ethylitaconimide, N-butylitaconimide, N-octylitaconimide, N-2-ethylhexylitaconimide, N-cyclohexylitaconimide, and N-laurylitaconimide; a succinimide-based unsaturated monomer such as N-(meth)acryloyloxymethylene succinimide, N-(meth)acryloyl-6-oxyhexamethylene succinimide, and N-(meth)acryloyl-8-oxyoctamethylene succinimide; a vinyl monomer such as vinyl acetate, vinyl propionate, N-vinyl pyrrolidone, methyl vinyl pyrrolidone, vinyl pyridine, vinyl piperidone, vinyl pyrimidine, vinyl piperazine, vinyl pyrazine, vinyl pyrrole, vinyl imidazole, vinyl oxazole, vinyl morpholine, N-vinyl carboxylic acid amides, styrene, α-methylstyrene, and N-vinyl caprolactam; a cyano group-containing unsaturated monomer such as acrylonitrile and methacrylonitrile; an epoxy group-containing acrylic monomer such as glycidyl(meth)acrylate; an ether-based acrylate monomer such as polyethylene glycol(meth)acrylate, polypropylene glycol(meth)acrylate, methoxyethylene glycol(meth)acrylate, and methoxypolypropylene glycol(meth)acrylate; a vinyl group-containing heterocycle compound such as tetrahydroflufuryl(meth)acrylate; a halogen atom-containing acrylate-based monomer such as fluorine(meth)acrylate; a silicone(meth)acrylate such as (meth)acryloyloxymethyl-trimethoxysilane; a polyfunctional monomer such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerythritol tri(meth)acrylate, dipentaerythritol hexa(meth)acrylate, epoxy acrylate, polyester acrylate, and urethane acrylate; a conjugated monomer such as isoprene, butadiene, and isobutylene; and a vinyl ether-based monomer such as vinyl ether.

The mixing ratio of the copolymerizable monomer in the monomer component with respect to 100 parts by mass of the monomer component is, for example, 50 parts by mass or less.

In order to prepare the acrylic polymer, the monomer component is, for example, polymerized by a known polymerization method such as a solution polymerization, a bulk polymerization, and an emulsion polymerization.

The silicone pressure-sensitive adhesive contains, for example, a silicone rubber and a silicone resin that contain an organopolysiloxane as a main component.

An example of the silicone rubber includes an organopolysiloxane containing dimethylsiloxane and/or diphenylsiloxane as a main constitutional unit. A vinyl group and another functional group may be introduced into the organopolysiloxane as required.

An example of the silicone resin includes an organopolysiloxane prepared from a copolymer having at least one unit (in units, R represents a monovalent hydrocarbon group or a hydroxyl group) selected from any one of M unit (R₃SiO_{1/2}), Q unit (SiO₂), T unit (RSiO_{3/2}), and D unit (R₂SiO) as a monomer unit. The organopolysiloxane prepared from the copolymer has an OH group and furthermore, various functional groups such as a vinyl group may be introduced thereto as required. The functional group may be subjected to a cross-linking reaction. A preferable example of the above-described copolymer includes a copolymer (MQ resin) having M unit and Q unit as a monomer unit.

The mixing ratio (in mass ratio, the silicone rubber:silicone resin) of the silicone rubber to the silicone resin is, for example, 100:100 to 100:170.

A known cross-linking agent and/or catalyst can be also blended into the silicone pressure-sensitive adhesive at an appropriate proportion.

An example of the rubber pressure-sensitive adhesive includes a rubber pressure-sensitive adhesive containing a rubber component as a base polymer. Examples of the rubber component include a natural rubber, a styrene-isoprene-styrene block copolymer (an SIS block copolymer), a styrene-butadiene-styrene block copolymer (an SBS block copolymer), a styrene-ethylene-butylene-styrene block copolymer (an SEBS block copolymer), a styrene-butadiene copolymer, a polybutadiene, a polyisoprene, a polyisobutylene, a butyl rubber, and a chloroprene rubber.

Of the pressure-sensitive adhesives, preferably, in view of transparency, an acrylic pressure-sensitive adhesive and a silicone pressure-sensitive adhesive are used, or more preferably, in view of pressure-sensitive adhesive properties, an acrylic pressure-sensitive adhesive is used.

The content ratio of the polymer with respect to the entire pressure-sensitive adhesive layer 2 is, for example, 10 mass % or more, preferably 30 mass % or more, or more preferably 50 mass % or more, and is, for example, 100 mass % or less.

A wavelength conversion material can be also contained in the pressure-sensitive adhesive layer 2.

The wavelength conversion material is uniformly dispersed in the polymer. The wavelength conversion material is a material that converts a wavelength of light, to be more specific, light that enters a solar cell element 3 (described later, ref: FIG. 4) to the high wavelength side.

An example of the wavelength conversion material includes a dye such as an organic dye and an inorganic dye.

Examples of the organic dye include a perylene derivative dye, a benzotriazole derivative dye, and a benzothiadiazole derivative dye and combinations thereof.

The perylene derivative dye is a perylene diester derivative, for example, represented by the following general formula (I) or general formula (II),

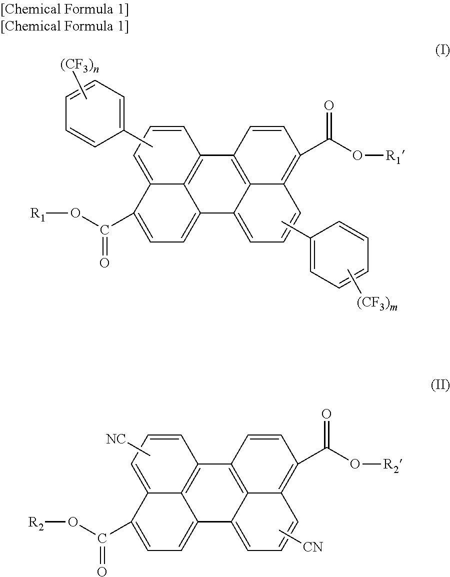

wherein, in formulas, R₁ and R₁′ in formula (I) are independent and are selected from the group consisting of hydrogen, C₁ to C₁₀ alkyl, C₃ to C₁₀ cycloalkyl, C₁ to C₁₀ alkoxy, C₆ to C₁₈ aryl, and C₆ to C₂₀ aralkyl. “m” and “n” in formula (I) are independent and are in a range of 1 to 5. R₂ and R₂′ in formula (II) are independent and are selected from the group consisting of C₆ to C₁₈ aryl and C₆ to C₂₀ aralkyl. When one of the cyano groups in formula (II) is at position 4 of a perylene ring, the other cyano group is not at position 10 of the perylene ring but at position 11 or position 12 of the perylene ring. When one of the cyano groups in formula (II) is at position 10 of the perylene ring, the other cyano group is not at position 4 of the perylene ring but at position 5 or position 6 of the perylene ring.

In formulas, R₁ and R₁′ are independent and are selected from the group consisting of hydrogen, C₁ to C₆ alkyl, C₂ to C₆ alkoxy, and C₆ to C₁₈ aryl. R₁ and R₁′ are independent and are selected from the group consisting of isopropyl, isobutyl, isohexyl, isooctyl, 2-ethyl-hexyl, diphenylmethyl, trityl, and diphenyl. R₂ and R₂′ are independent and are selected from the group consisting of diphenylmethyl, trityl, and diphenyl. “m” and “n” in formula (I) are independent and are in a range of 1 to 4.

The perylene diester derivative represented by general formula (I) or general formula (II) is capable of being fabricated by a known method described in U.S. Provisional Applications No. 61/430,053 and No. 61/485,093. The contents of both documents are incorporated into the present description by reference in their entirety.

The benzotriazole derivative dye is a derivative containing a 2H-benzo[d][1,2,3]triazole heterocyclic system represented by the following general formula (III).

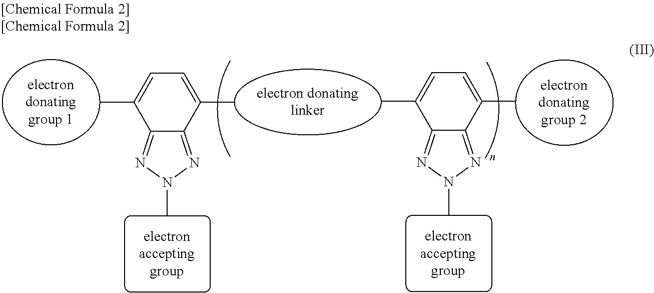

“n” in formula (III) is an integer in a range of 0 to 100. When “n” is 0, the following conditions can be applied. (1) Electron accepting groups at position 2 of N are a portion that reduces the electron density of the 2H-benzo[d][1,2,3]triazole system. (2) An electron donating group 1 at position 4 of C and an electron donating group 2 at position 7 of C are the same or different from each other. Of the electron donating groups, at least one is a portion that increases the electron density of the 2H-benzo[d][1,2,3]triazole system. The other electron donating group is a portion that increases the electron density of the 2H-benzo[d][1,2,3]triazole system, a portion that has a neutral effect with respect to the electron density, or hydrogen.

In formula (III), when “n” is in a range of 1 to 100, the following conditions (1) to (3) can be applied.

(1) Electron accepting groups at position 2 of N are independent and are selected from the same or different group(s). Each of the electron accepting groups includes a portion that reduces the electron density of a 2H-benzo[d][1,2,3]triazole subunit to which the group is bonded. (2) An electron donating linker group is bonded to two pieces of 2H-benzo[d][1,2,3]triazole units at position 4 of C and position 7 of C. (3) Of the electron donating group 1, the electron donating group 2, and the electron donating linker group, at least one is a portion or a linker that increases the electron density of the 2H-benzo[d][1,2,3]triazole unit to which the group is bonded. The remaining electron donating group and/or electron donating linker group include(s) a portion or a linker that increases the electron density of the 2H-benzo[d][1,2,3]triazole system to which the group(s) are/is bonded or a portion or a linker that has a neutral effect with respect to the electron density. The remaining electron donating group 1 or electron donating group 2 may contain hydrogen.

The electron donating groups 1 and 2 are the same or different from each other. When “n” in formula (III) is an integer in a range of 2 to 100, the electron donating linker groups are the same or different from each other.

An atom with a number in the 2H-benzo[d][1,2,3]triazole system is defined as follows.

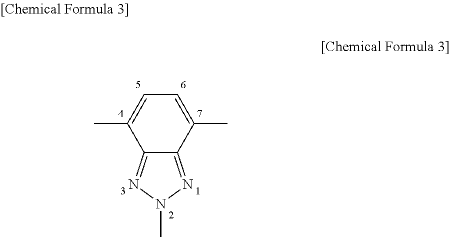

The “electron donating group” is defined as an arbitrary group that increases the electron density of a 2H-benzo[d][1,2,3]triazole system. The “electron donating linker” is defined as an arbitrary group that is bonded to two pieces of 2H-benzo[d][1,2,3]triazole systems and is capable of imparting conjugation of pi orbital and is capable of increasing the electron density of the 2H-benzo[d][1,2,3]triazole systems to which the group is bonded or has a neutral effect with respect to the electron density. The “electron accepting group” is defined as an arbitrary group that reduces the electron density of a 2H-benzo[d][1,2,3]triazole system. When the electron accepting group is disposed at position 2 of N of a 2H-benzo[d][1,2,3]triazole cyclic system, an excellent unexpected advantage is obtained.

Preferably, the electron accepting group remarkably reduces the electron density of the triazole ring. The electron accepting group includes a phenyl ring that has at least one electron-withdrawing substituent at an ortho position or a para position and has a further substituent or fails to have a substituent. The electron accepting group may include, for example, a portion represented by the following formula.

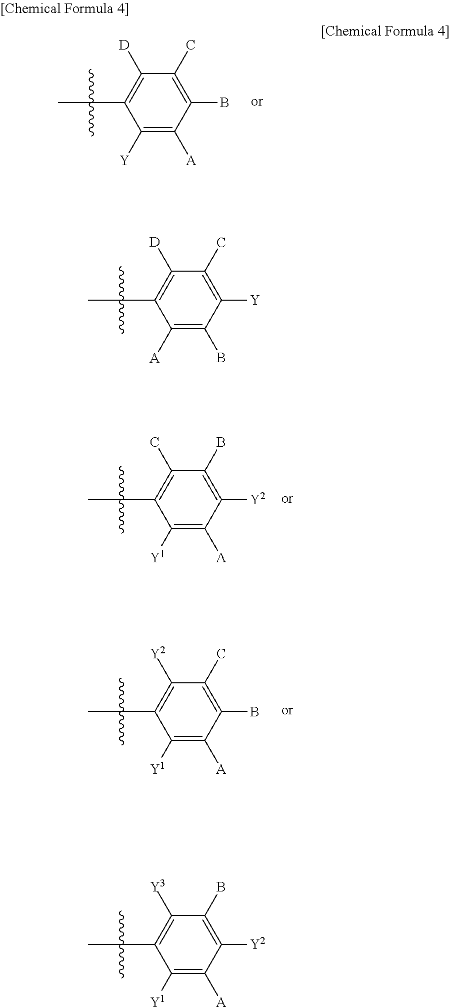

In the electron accepting group, Y, Y¹, Y², and Y³ are independent and are selected from the group consisting of —NO₂ group, —C≡N group, CH═N—Ar group, N═N—Ar group, N═CH—Ar group, —C(═O)R group, —C(═O)OR group, and —C(═O)NR¹R² group. Ar is an aryl group. In the electron accepting group, R, R¹, and R² are independent and are selected from the group consisting of hydrogen, substituted alkyl, unsubstituted alkyl, substituted aryl, and unsubstituted aryl. Typically, the substituents A, B, C, and D are hydrogen, a substituted alkyl, an unsubstituted alkyl, a substituted aryl, or an unsubstituted aryl. These may include an arbitrary electron-withdrawing group or electron donating group. Furthermore, a pair of substituents A and B, C and D, or B and C may be bonded to each other to form one or more condensed ring(s). Examples of the condensed ring include naphthalene, anthracene, phenanthrene, and pyrene.

The electron accepting group includes a heterocyclic ring that has a further substituent or fails to have a further substituent and is lack of an electron. A basic example of the structure is shown in the following.

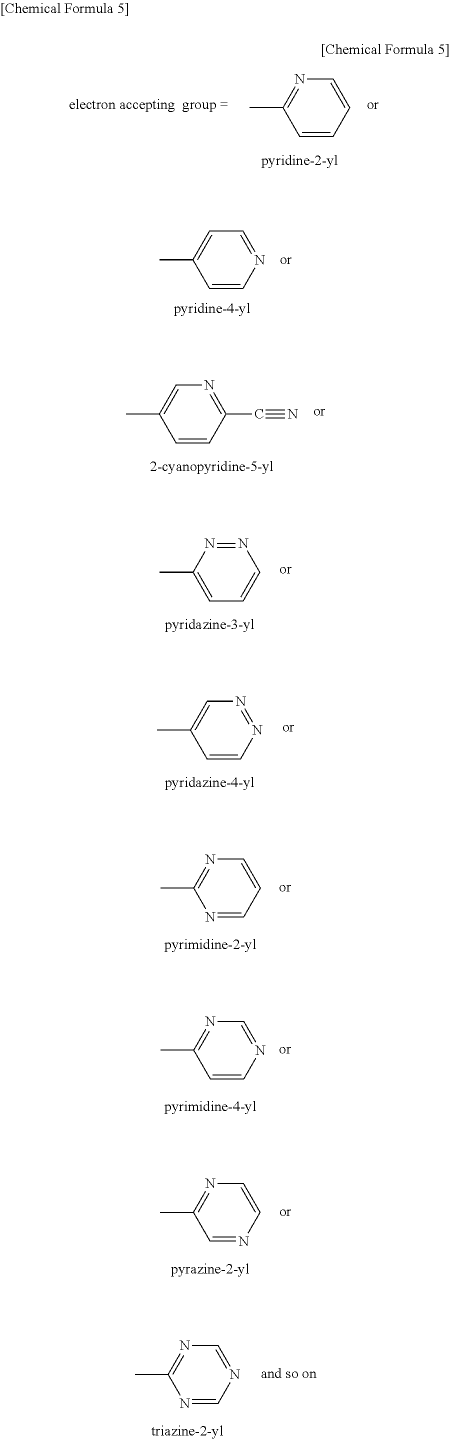

As shown in examples represented in the following, the heterocyclic ring lack of an electron may be condensed with benzene or another heterocyclic ring. In all of the molecules, the ring may be as it is or may be derivatized with an arbitrary substituent.

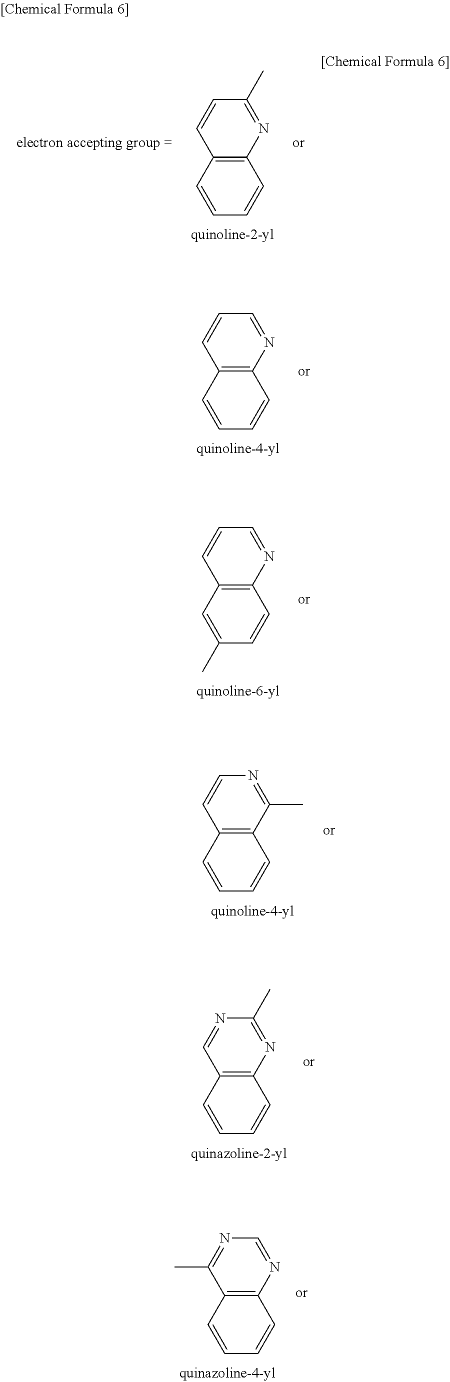

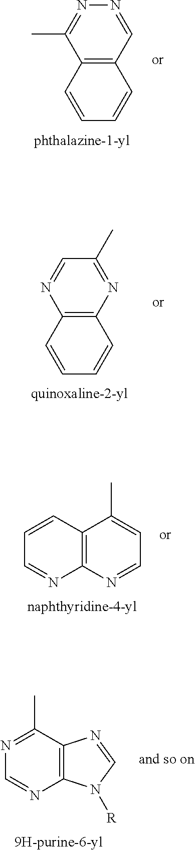

In this case, another option of the electron donating group includes an electron-withdrawing group that is bonded to position 2 of N of the benzotriazole system via a double bond. As a promising compound of this type, the following compound is used.

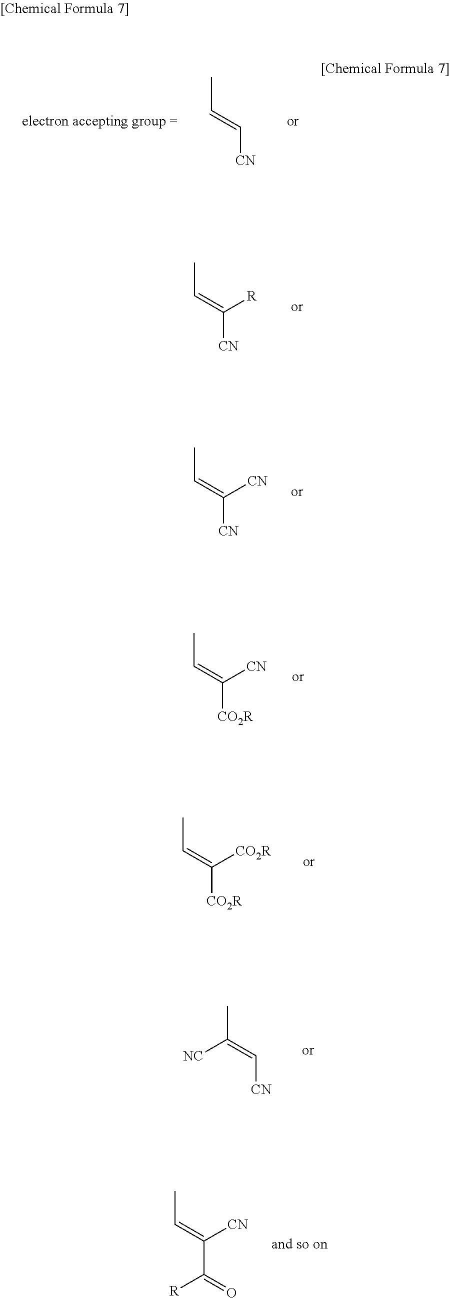

A chromophore in general formula (III) includes at least one electron donating group. A second electron donating position in general formula (III) may be occupied with another electron donating group, a hydrogen atom, or another neutral substituent. A typical electron donating group is widely reported in documents and all of the groups are appropriate for use in the disclosed invention. The electron donating groups 1 and 2 in general formula (III) may be the same or different from each other.

As shown in the following, the electron donating portion is a phenyl ring that has at least one electron donating hetero atom substituent X (N, O, or S) at the ortho position or the para position.

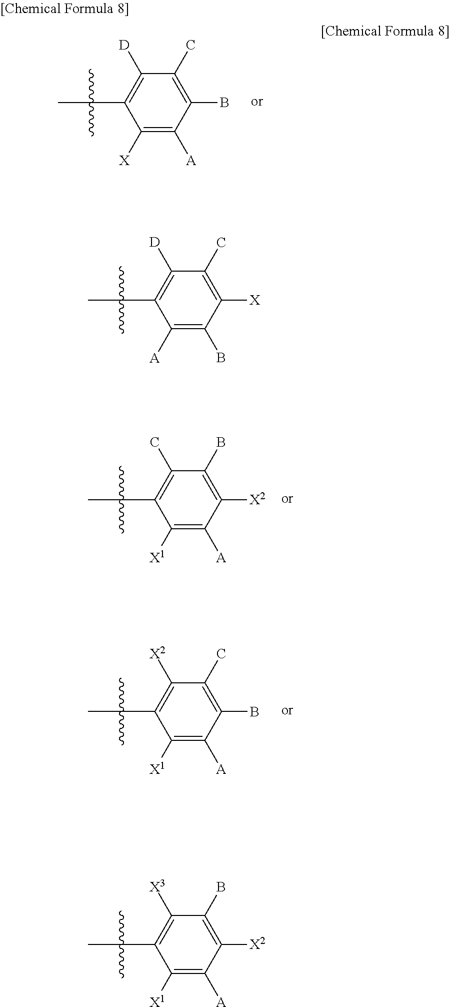

In the electron donating portion, X, X¹, X², and X³ are independent and are selected from the group consisting of —NR₂, NR¹R², —NRCOR¹, —OR, —OCOR, and —SR. R, R¹, and/or R² are independent and are selected from the group consisting of hydrogen, substituted alkyl, unsubstituted alkyl, substituted alkyl, and unsubstituted aryl. In the electron donating portion, the substituents A, B, C, and D are selected from the group consisting of hydrogen, a substituted alkyl, an unsubstituted alkyl, a substituted aryl, an unsubstituted aryl, and an arbitrary group containing a hetero atom. The X group, the X¹ group, the X² group, and the X³ group may be directly bonded to a benzotriazole nucleus.

A condensed aromatic ring that has a substituent or fails to have a substituent forms another group that has an electron donating portion. Examples of the ring are shown in the following.

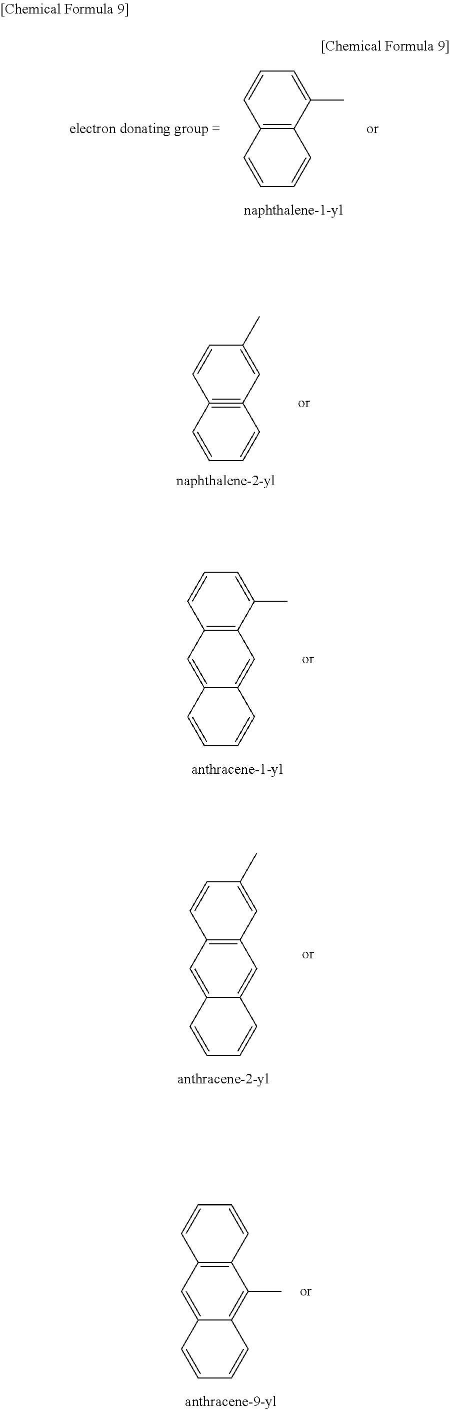

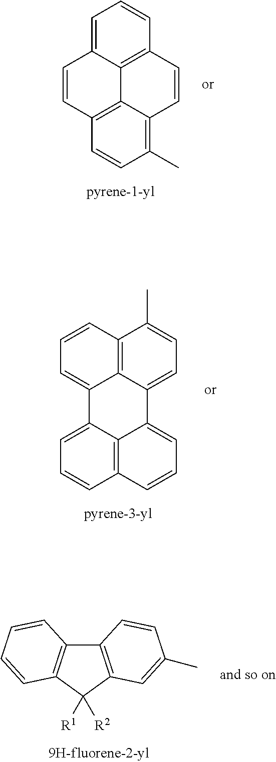

The electron donating group is a heterocyclic ring and is, for example, a heterocyclic ring that has abundant electrons shown in the following. The ring may be substituted according to circumstances.

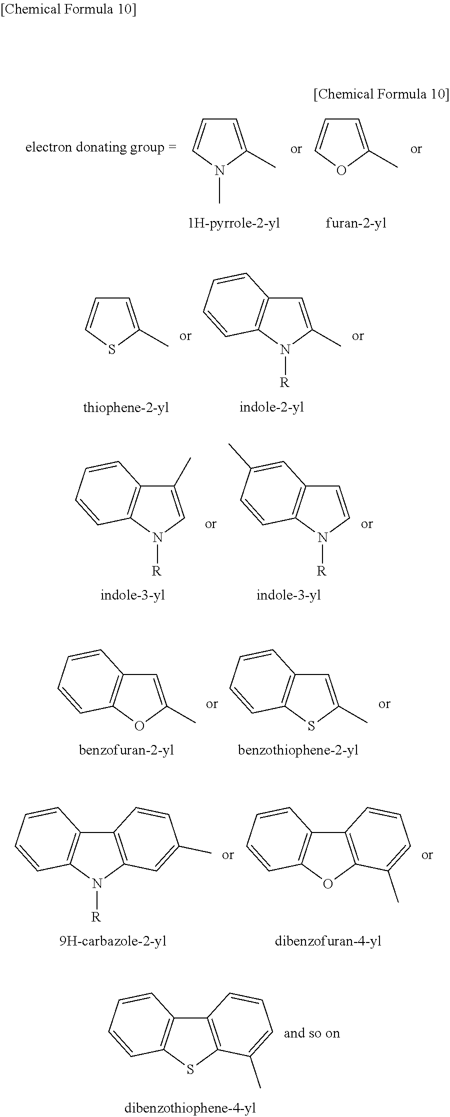

When “n” in formula (III) is 1 or more, two or more benzotriazole-2-yl systems are bonded by a linker group and a more complicated structure is generated. In this case, general formula (III) includes an electron donating linker group. Of the electron donating group 1, the electron donating group 2, and the electron donating linker group, at least one must be a group that increases the electron density of the 2H-benzo[d][1,2,3]triazole system to which the group is bonded. The electron donating groups 1 and 2 are defined as the description above, and may be a hydrogen atom or another arbitrary neutral group that fails to affect the electron density of the 2H-benzo[d][1,2,3]triazole system to which the groups are bonded. The number “n” of repeating unit may fluctuate from 1 to 100. The electron linker represents a conjugated electron system and may be neutral. The electron linker itself may also function as an electron donating group. Of the linkers, a typical structure made of carbon atoms only is shown in the following. The structure may include or fail to include a further bonded substituent.

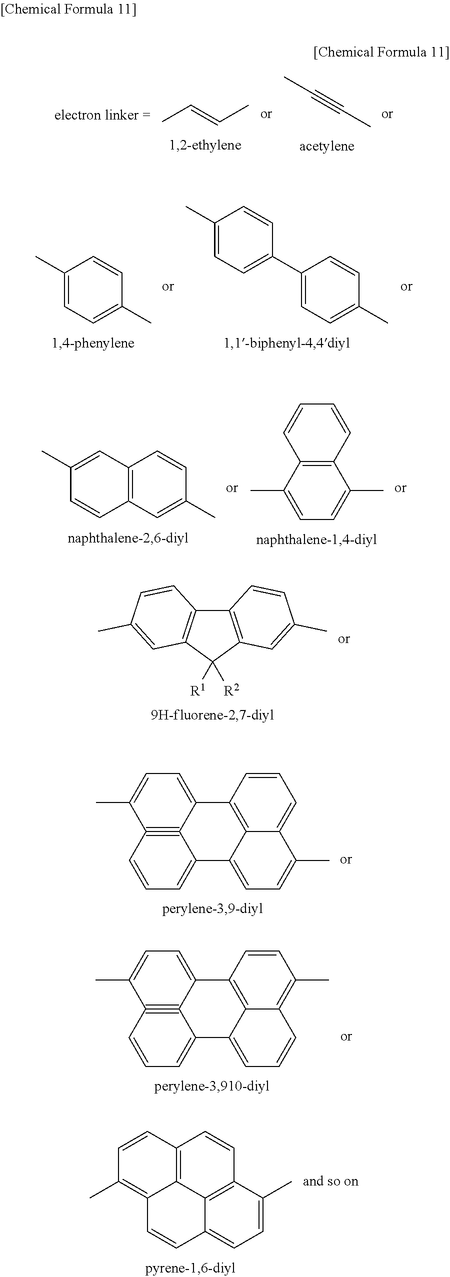

The electron donating linker may include a heterocycle block shown in the following. Combinations of linkers such as two carbon-carbon, heterocycle-heterocycle, and carbon-heterocycle are possible. R, R¹, and R² in the structure represent an arbitrary substituted or unsubstituted alkyl group or an arbitrary substituted or unsubstituted aryl group.

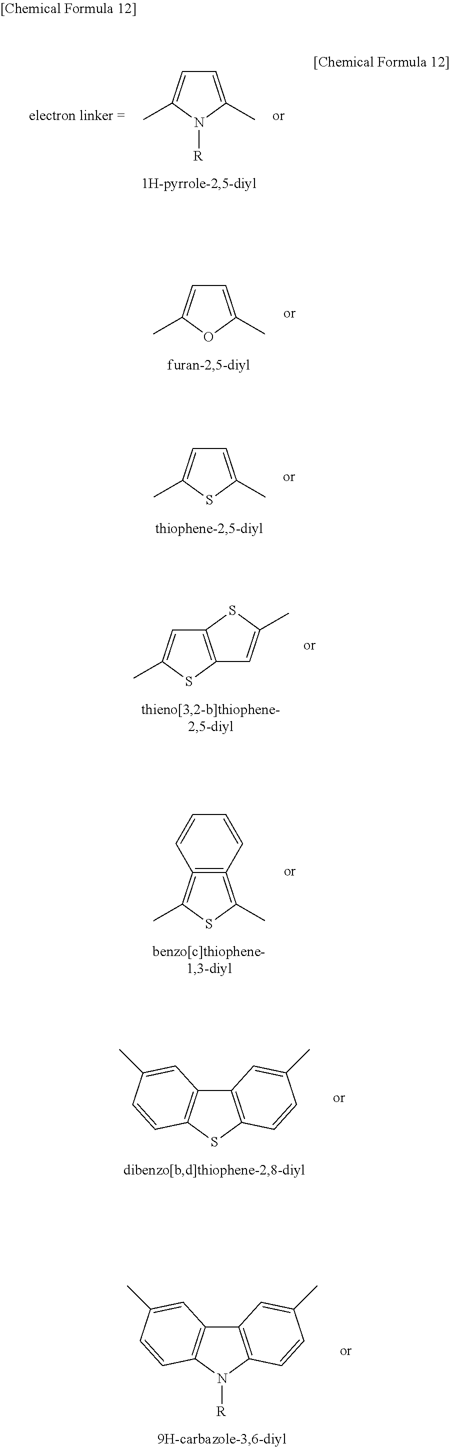

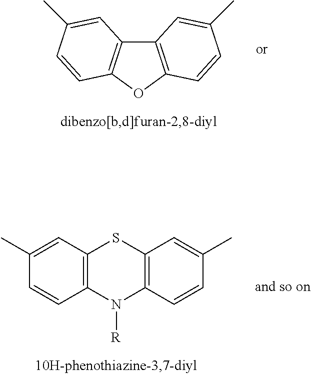

The 2H-benzo[d][1,2,3]triazole derivative represented by general formula (III) may be fabricated by a known method, for example, a method described in U.S. Provisional Application No. 61/539,392 in which the contents thereof are incorporated into the present description by reference in their entirety.

Furthermore, as shown in the following general formula (IV), an example of the organic dye includes a chromophore derivative in which a heterocyclic system to which two electron donating groups are bonded is contained as the electron accepting group in its center and at least one of the electron donating groups is bonded to a carbonyl group.

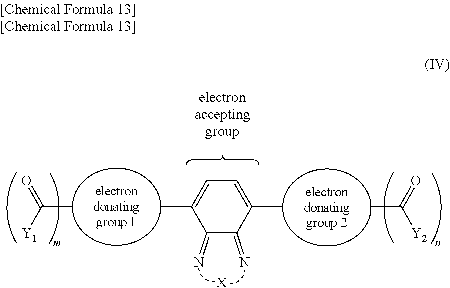

In formula (IV), X is selected from the group consisting of —O—, —S—, —Se—, —Te—, —NR—, —CR═CR—, and —CR═N— and R is hydrogen, a substituted alkyl, an unsubstituted alkyl, a substituted aryl, or an unsubstituted aryl. The electron donating groups are the same or different from each other. The electronic influence of the electron donating group imparted to a benzenoid ring is adjusted by a carbonyl group. In formula (IV), “m” is 1 or 2 and “n” is 0, 1, or 2. Y₁ and Y₂ are independent and are selected from the group consisting of R, OR, NHR, and NR₂. R is hydrogen, a, substituted alkyl, an unsubstituted alkyl, a substituted aryl, an unsubstituted aryl, or heteroaryl. The electron donating group in general formula (IV) may include a portion or a plurality of portions that is/are defined about the benzotriazole compound in the description above.

Preferably, the organic dye is a chromophore derivative that contains a heterocyclic system represented by the following general formula (V).

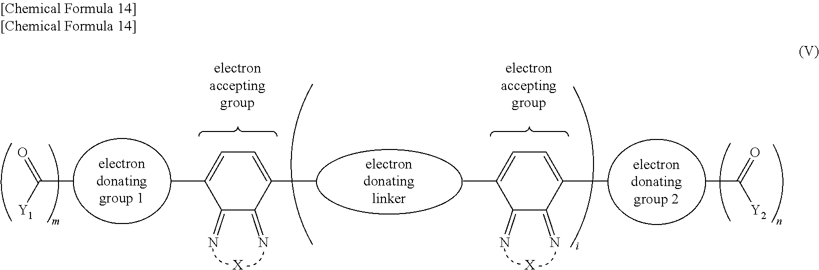

“i” in formula (V) is an integer in a range of 1 to 100. In formula (V), X and Xᵢ (X₁, X₂, X₃, and the like to X) are independently selected from the group consisting of —O—, —S—, —Se—, —Te—, —NR—, —CR═CR—, and —CR═N— and R is hydrogen, a substituted alkyl, an unsubstituted alkyl, a substituted aryl, or an unsubstituted aryl. The electron donating groups are the same or different from each other. The electron linker groups are the same or different from each other. The electronic influence of the electron donating group imparted to a benzenoid ring is adjusted by a carbonyl group. In formula (V), “m” is 1 or 2 and “n” is 0, 1, or 2. Y₁ and Y₂ are independent and are selected from the group consisting of R, OR, NHR, and NR₂. R is hydrogen, a substituted alkyl, an unsubstituted alkyl, a substituted aryl, an unsubstituted aryl, or heteroaryl. The electron donating group and the electron donating linker group in general formula (V) may include a portion or a plurality of portions that is/are defined about the benzotriazole compound in the description above.

A commercially available product can be used as the organic dye. An example of an organic phosphor dye includes the Lumogen F series (manufactured by BASF Japan Ltd.). To be specific, examples of the Lumogen F series include Lumogen F Violet 570, Lumogen F Blue 650, Lumogen F Green 850, Lumogen F Yellow 083, and Lumogen F Yellow 170.

An example of the inorganic dye includes an inorganic phosphor such as a red light-emitting inorganic phosphor, a green light-emitting inorganic phosphor, and a blue light-emitting inorganic phosphor.

Examples of the red light-emitting inorganic phosphor include Y₃O₃:Eu, YVO₄:Eu, Y₂O₂:Eu, 3.5MgO.0.5MgF₂, GeO₂:Mn, and (Y.Cd)BO₂:Eu.

Examples of the green light-emitting inorganic phosphor include ZnS:Cu.Al, (Zn.Cd)S:Cu.Al, ZnS:Cu.Au.Al, Zn₂SiO₄:Mn, ZnSiO₄:Mn, ZnS:Ag.Cu, (Zd.Cd)S:Cu, ZnS:Cu, GdOS:Tb, LaOS:Tb, YSiO₄:C.Tb, ZnGeO₄:Mn, GeMgAlO:Tb, SrGaS:Eu²⁺, ZnS:Cu.Co, MgO.nB₂O₃:Ge.Tb, LaOBr:Tb.Tm, and La₂O₂S:Tb.

Examples of the blue light-emitting inorganic phosphor include ZnS:Ag, GaWO₄, Y₂SiO₆:Ce, ZnS:Ag.Ga.Cl, Ca₂B₄OCl:Eu²⁺, and BaMgAl₄O₃:Eu²⁺.

The excitation spectrum of the wavelength conversion material has a peak wavelength at, for example, 350 to 550 nm, or preferably 370 to 500 nm.

The fluorescence spectrum of the wavelength conversion material has a peak wavelength at, for example, 400 to 700 nm, or preferably 420 to 600 nm.

The excitation spectrum and the fluorescence spectrum of the wavelength conversion material are obtained by preparing a sample by kneading the wavelength conversion material in the polymer to be used in a known fluorescence spectrophotometer.

When the excitation spectrum and the fluorescence spectrum of the wavelength conversion material are within the above-described range, the wavelength (for example, a short wavelength of 300 nm or more and less than 350 nm) of light is capable of being efficiently converted to a higher wavelength side (for example, a long wavelength of 350 nm or more and less than 500 nm).

Of the above-described dyes, preferably, an organic dye is used.

The mixing ratio of the wavelength conversion material with respect to 100 parts by mass of the polymer is, for example, 0.001 to 10 parts by mass, preferably 0.01 to 5 parts by mass, or more preferably 0.01 to 3 parts by mass.

When the mixing proportion of the wavelength conversion material is above the above-described range, the transparency of the pressure-sensitive adhesive layer 2 may be reduced. On the other hand, when the mixing proportion of the wavelength conversion material is below the above-described range, it may be difficult to obtain the effect of the wavelength conversion.

A known additive can be also added to the pressure-sensitive adhesive layer 2 at an appropriate proportion. Examples of the known additive include a cross-linking agent, a tackifier, a peel adjusting agent, a plasticizer, a softer, an oxidation inhibitor, and a deterioration inhibitor.

The pressure-sensitive adhesive layer 2 has a peel pressure-sensitive adhesive force at 180 degrees with respect to a stainless steel board at 25° C. of 0.1 N/20 mm to 100 N/20 mm.

When the pressure-sensitive adhesive force is below the above-described range, the pressure-sensitive adhesive force with respect to a protective member 6 may be reduced. On the other hand, when the pressure-sensitive adhesive force is above the above-described range, there may be a case where the removability is poor and the re-attachment is not possible, so that the productivity is reduced.

The pressure-sensitive adhesive layer 2 has a haze value, in the case of a thickness of 0.1 mm, of, for example, 50 or less, or preferably 20 or less. The haze value is measured with, for example, a haze meter.

The pressure-sensitive adhesive layer 2 has a thickness of, for example, 1 to 500 μm, preferably 5 to 300 μm, or more preferably 10 to 200 μm.

When the thickness of the pressure-sensitive adhesive layer 2 is below the above-described range, in the case where the pressure-sensitive adhesive layer 2 contains a wavelength conversion material, it may be difficult to obtain the effect of the wavelength conversion. When the thickness of the pressure-sensitive adhesive layer 2 is above the above-described range, the transparency of the pressure-sensitive adhesive layer 2 may be reduced.

The substrate 4 is formed on the entire back surface of the pressure-sensitive adhesive layer 2.

An example of the substrate 4 includes a substrate sheet such as a polymer film (polyethylene terephthalate (PET), polyvinyl chloride (PVC), polyimide (PI), polybutylene terephthalate (PBT), polyphenylene sulfide (PPS), and an ethylene vinyl acetate copolymer (EVA)) that is subjected to a surface treatment with a silicone-based, a long chain alkyl-based, a fluorine-based, or a molybdenum sulphide release agent and paper. Furthermore, examples of the polymer film include a low adhesive property substrate sheet prepared from a fluorine-based polymer such as polytetrafluoroethylene (PTFE), polychlorotrifluoroethylene, polyvinyl fluoride, polyvinylidene fluoride, a tetrafluoroethylene and hexafluoropropylene copolymer, and a chlorofluoromethylene and vinylidene fluoride copolymer and a low adhesive property substrate sheet prepared from a non-polar polymer such as an olefin resin (for example, polyethylene (PE), polypropylene (PP), and the like).

When the substrate 4 is prepared from a polymer film, the above-described wavelength conversion material is also capable of being blended therein. The mixing ratio of the wavelength conversion material with respect to 100 parts by mass of the polymer is, for example, 0.001 to 10 parts by mass, preferably 0.01 to 5 parts by mass, or more preferably 0.01 to 3 parts by mass.

The substrate 4 has an elastic modulus at 25° C. measured in a tensile test of 1 MPa to 9×10³ MPa, preferably 3 MPa to 9×10³ MPa, or more preferably 10 MPa to 9×10³ MPa.

The elastic modulus of the substrate 4 at 25° C. is measured in conformity with the measurement method of JIS K7113.

When the elastic modulus of the substrate 4 is above the above-described range, the substrate 4 is too hard, so that stress caused by contact with another protective member 6 is not capable of being sufficiently eased and thus, damage to the protective member 6 is not capable of being effectively prevented.

On the other hand, when the elastic modulus of the substrate 4 is below the above-described range, the substrate 4 is too soft, so that a buffer action by the substrate 4 is reduced and thus, damage to the protective member 6 is not capable of being effectively prevented.

The substrate 4 has a thickness of, for example, 1 to 300 μm, or preferably 5 to 100 μm.

In order to obtain the pressure-sensitive adhesive sheet 1 shown in FIG. 1, first, the above-described components are blended. To be specific, a pressure-sensitive adhesive, if necessary, a wavelength conversion material, and, if necessary, an additive are put into a solvent to be uniformly mixed, so that a coating liquid is prepared. Examples of the solvent include an aromatic solvent such as toluene, benzene, and xylene; a ketone-based solvent such as acetone; and water.

Next, the prepared coating liquid is applied to the entire top surface of the substrate 4 by a known coating method such as a roll coating method and a knife coating method.

After the application of the coating liquid, the resulting laminate is heated and dried. In this way, the pressure-sensitive adhesive sheet 1 including the pressure-sensitive adhesive layer 2 and the substrate 4 is obtained.

FIG. 2 shows a sectional view of one embodiment of a protection unit of the present invention in which the pressure-sensitive adhesive sheet shown in FIG. 1 is used. FIG. 3 shows a sectional view of a state in which a plurality of the protection units shown in FIG. 2 are laminated.

Next, the protection unit 8 in which the above-described pressure-sensitive adhesive sheet 1 is used is described with reference to FIGS. 2 and 3.

In FIG. 2, the protection unit 8 includes the protective member 6 and the pressure-sensitive adhesive sheet 1 formed on the top surface (one surface in the thickness direction) of the protective member 6.

The protective member 6 is provided on the backmost surface (the outermost one surface in the thickness direction) in the protection unit 8. The protective member 6 is formed into a flat plate shape.

An example of a material that forms the protective member 6 includes a transparent material, to be specific, a transparent material that usually substantially fails to absorb light entering the solar cell element 3 (ref: FIG. 4). To be specific, an example of the material includes glass.

The top surface (the opposing surface that is opposed to the pressure-sensitive adhesive layer 2) of the protective member 6 is subjected to a surface treatment such as an antireflection (AR) treatment and/or an antiglare (AG) treatment, so that a treated layer is also capable of being formed. The surface treatment is, for example, performed in conformity with a method described in Japanese Unexamined Patent Publications No. 2011-146529, No. 2010-141111, No. 2003-110131, and No. 2004-111453.

The surface roughness of the protective member 6 is the ten point average roughness in conformity with JIS B 0601-1994 and is, for example, 0.1 to 1000 μm, or preferably 0.5 to 500 μm.

The protective member 6 has a thickness of, for example, 1 to 12 mm.

The pressure-sensitive adhesive layer 2 in the pressure-sensitive adhesive sheet 1 is attached to the entire top surface (in the case of being subjected to a surface treatment, the surface of the treated layer) of the protective member 6.

The substrate 4 is provided on the topmost surface (the outermost other surface in the thickness direction) in the protection unit 8. The substrate 4 is disposed in opposed relation to the protective member 6 in the thickness direction (a top-back direction) so as to sandwich the pressure-sensitive adhesive layer 2 between the substrate 4 and the protective member 6.

In order to obtain the protection unit 8 shown in FIG. 2, first, the protective member 6 is prepared.

Next, the pressure-sensitive adhesive sheet 1 shown in FIG. 1 is reversed upside down and the pressure-sensitive adhesive layer 2 in the pressure-sensitive adhesive sheet 1 is attached to the top surface of the protective member 6.

In this way, the protection unit 8 is obtained.

Thereafter, as shown in FIG. 3, a plurality of the protection units 8 are, for example, laminated to be conveyed or stored. In the laminate made of a plurality of the protection units 8, the substrate 4 in one protection unit 8 is disposed adjacent to the protective member 6 in another protection unit 8 that is laminated on the back side of the one protection unit 8 and this adjacent state is repeated in a lamination (the top-back) direction. That is, the pressure-sensitive adhesive layer 2 and the substrate 4 are interposed between a plurality of the protective members 6 that are laminated.

In the protection unit 8, the pressure-sensitive adhesive layer 2 is attached to the protective member 6 and the elastic modulus of the substrate 4 that is formed on the top surface (the other surface in the thickness direction) of the pressure-sensitive adhesive layer 2 is within a specific range, so that the mechanical strength of the protection unit 8 is capable of being improved and thus, damage to the protective member 6 is capable of being effectively prevented.

Among all, when the treated layer prepared by the above-described treatment is formed on the top surface of the protective member 6, the treated layer may be damaged by contact with another protective member 6 that is laminated.

In this embodiment, however, as shown in FIG. 3, when a plurality of the protection units 8 are laminated to be conveyed or stored, the above-described pressure-sensitive adhesive layer 2 and substrate 4 are capable of being interposed between a plurality of the laminated protective members 6, so that damage to the protective member 6 caused by contact of the protective members 6 with themselves is capable of being prevented.

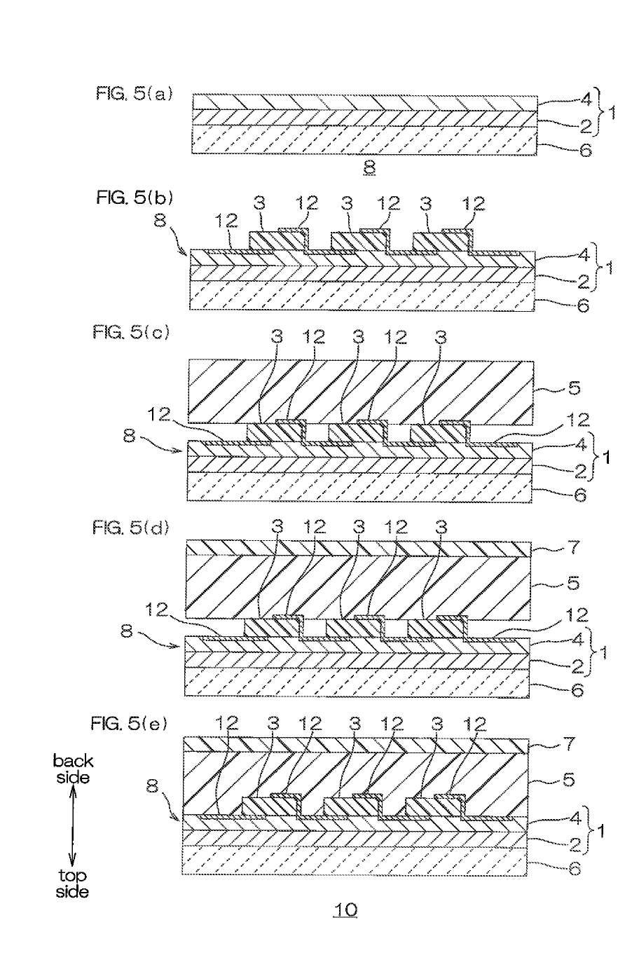

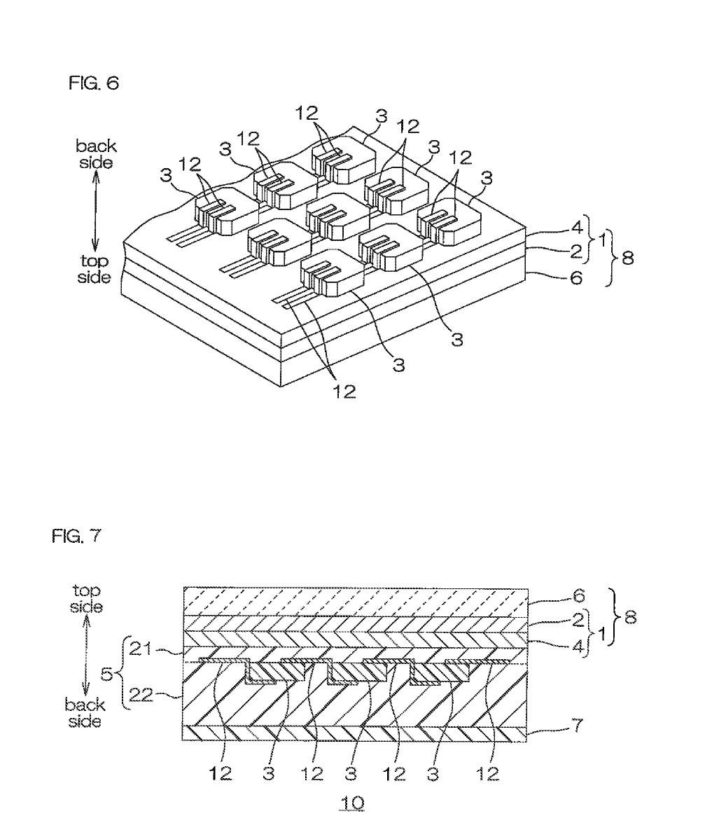

FIG. 4 shows a sectional view of a solar cell module in which the protection unit shown in FIG. 2 is used. FIG. 5 shows process drawings for illustrating a method for producing the solar cell module shown in FIG. 4. FIG. 6 shows a perspective view of the solar cell module in the middle of the production shown in FIG. 5 (b).

Next, the solar cell module 10 in which the protection unit 8 shown in FIG. 2 is used is described with reference to FIGS. 4 to 6.

In FIG. 4, the solar cell module 10 is formed into a generally rectangular sheet shape in plane view and includes the solar cell elements 3, an encapsulating layer 5, the protection unit 8, and a back sheet 7.

Each of the solar cell elements 3 is formed into a generally rectangular flat plate shape in plane view and is formed from a semiconductor such as a crystalline or amorphous silicon. As referred in FIG. 6, the solar cell elements 3 are disposed in alignment at spaced intervals to each other in a plane direction (a direction perpendicular to the thickness direction). A plurality of electrodes 12 are laminated on the top surfaces (one surfaces in the thickness direction) and the back surfaces (the other surfaces in the thickness direction) of the solar cell elements 3 that are adjacent to each other. The solar cell elements 3 that are adjacent to each other are electrically connected by the electrodes 12.

Each of the solar cell elements 3 has a thickness of, for example, 0.10 to 0.20 mm.

The encapsulating layer 5 encapsulates the solar cell elements 3. To be more specific, the encapsulating layer 5 is provided so as to cover the side surfaces and the back surfaces of the solar cell elements 3.

An example of an encapsulating material that forms the encapsulating layer 5 includes a polymer such as an ethylene-vinyl acetate copolymer (EVA), polyvinyl butyral (PVB), and polyvinylidene fluoride.

The thickness of the encapsulating layer 5 is thicker than that of the solar cell element 3. The encapsulating layer 5 has a thickness of, for example, 0.2 to 2 mm.

The protection unit 8 includes the protective member 6, the pressure-sensitive adhesive layer 2 that is attached to the back surface (the top surface in FIG. 2) thereof, and the substrate 4 that is formed on the back surface (the top surface in FIG. 2) of the pressure-sensitive adhesive layer 2.

The protective member 6 is provided on the topmost surface (the outermost one surface in the thickness direction) in the solar cell module 10.

The pressure-sensitive adhesive layer 2 is attached to the entire back surface of the protective member 6.

The substrate 4 is interposed between the pressure-sensitive adhesive layer 2, and the encapsulating layer 5 around the solar cell elements 3 and the solar cell elements 3. That is, the substrate 4 covers the top surfaces of the solar cell elements 3.

The back sheet 7 is provided on the backmost surface (the outermost other surface in the thickness direction) in the solar cell module 10 and is laminated on the back surface (the other surface in the thickness direction) of the encapsulating layer 5. The back sheet 7 is formed from, for example, a resin such as an olefin resin and a polyester resin. The back sheet 7 has a thickness of, for example, 0.05 to 0.3 mm.

Next, a method for producing the solar cell module 10 is described with reference to FIGS. 5 and 6.

In this method, first, as shown in FIG. 5 (a), the protection unit 8 (ref: FIG. 2) is prepared.

Next, as shown in FIGS. 5 (b) and 6, a plurality of the solar cell elements 3 in an aligned state are attached to the back surface of the substrate 4.

Next, as shown in FIG. 5 (c), the encapsulating layer 5 is disposed on the back surfaces of a plurality of the solar cell elements 3. The encapsulating layer 5, in a state before being heated, retains its sheet shape, so that the side surfaces of the solar cell elements 3 are exposed without being in contact with the encapsulating layer 5, while the back surfaces of the solar cell elements 3 are covered with the encapsulating layer 5.

Next, as shown in FIG. 5 (d), the back sheet 7 is disposed on the back surface of the encapsulating layer 5.

Thereafter, as shown in FIG. 5 (e), the obtained laminate is thermocompression bonded.

The heating temperature is, for example, 80 to 200° C., or preferably 100 to 160° C. and the pressure is, for example, 0.01 to 0.5 MPa, or preferably 0.01 to 0.2 MPa.

The encapsulating layer 5 is softened and melted by the thermocompression bonding and fills a space between the solar cell elements 3. In this way, the solar cell elements 3 are encapsulated.

In this way, the solar cell module 10 shown in FIG. 4 is obtained. The solar cell module 10 shown in FIG. 4 is obtained by allowing the solar cell module 10 shown in FIG. 5 (e) to be reversed upside down.

The above-described protection unit 8 is used in the solar cell module 10, so that the solar cell module 10 has excellent reliability.

In the solar cell module 10, the substrate 4 is provided on the back surface of the pressure-sensitive adhesive layer 2, so that when a wavelength conversion material is contained in the pressure-sensitive adhesive layer 2, after allowing light to pass through the pressure-sensitive adhesive layer 2, the wavelength of the light (sunlight) is capable of being converted before the light is absorbed by the substrate 4.

That is, before the light is absorbed by the substrate 4, the pressure-sensitive adhesive layer 2 is capable of efficiently performing wavelength conversion of light from light in short wavelength (for example, light having a wavelength of less than 350 nm) that is relatively easily absorbed by the substrate 4 to light in long wavelength (for example, light having a wavelength of 350 nm or more) that is relatively not easily absorbed by the substrate 4.

Thus, thereafter, even when the light in which the wavelength thereof is converted passes through the substrate 4, the light is less susceptible to absorption by the substrate 4 and in the solar cell element 3, the light in which the wavelength thereof is converted is capable of being efficiently photoelectrically converted, so that the photoelectric conversion efficiency of the solar cell module 10 is capable of being improved.

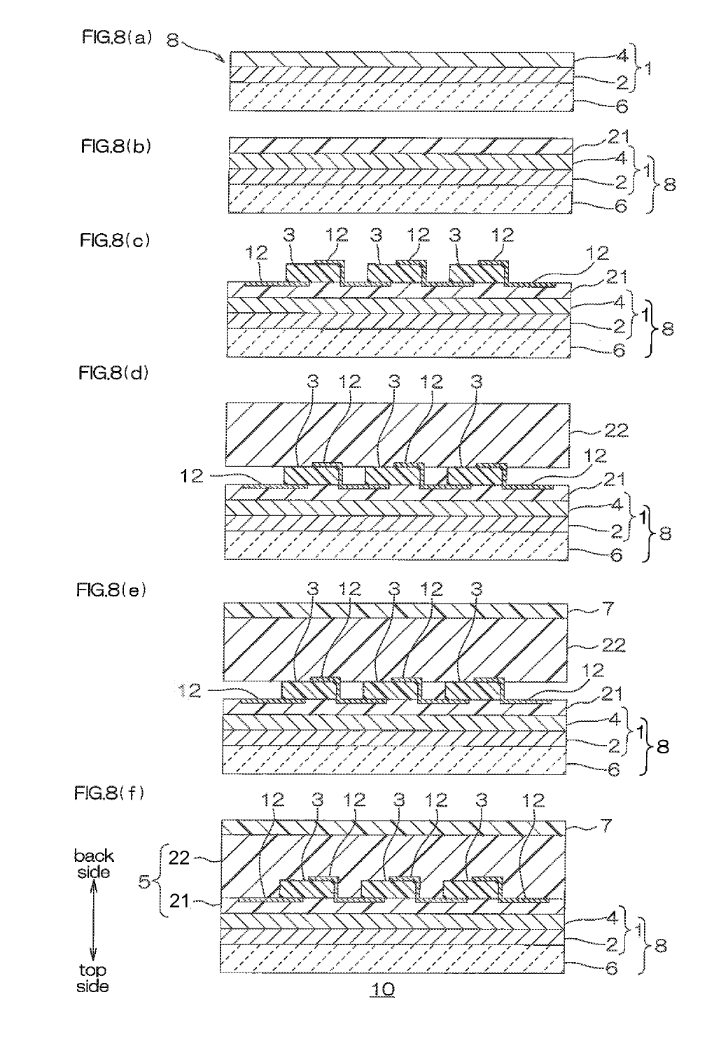

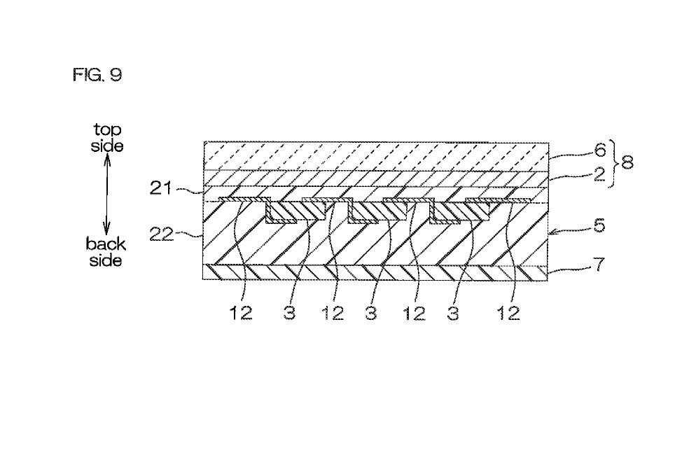

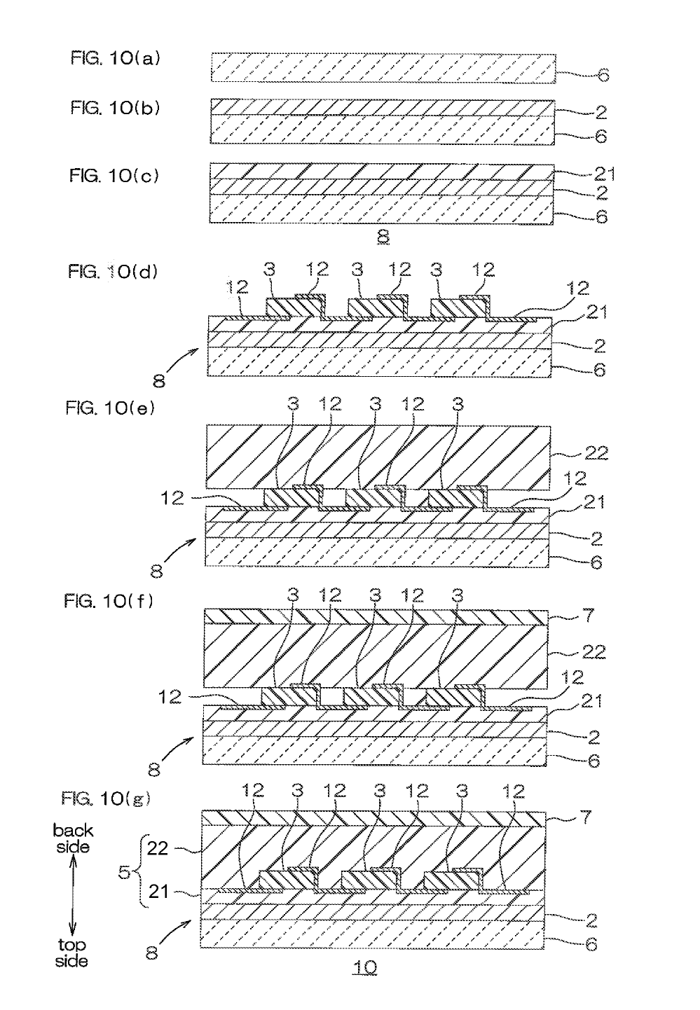

FIG. 7 shows a sectional view of another embodiment (an embodiment in which a support layer is made of a substrate and a first encapsulating layer) of a solar cell module of the present invention. FIG. 8 shows process drawings for illustrating a method for producing the solar cell module shown in FIG. 7. FIG. 9 shows a sectional view of another embodiment (an embodiment in which a support layer is made of a first encapsulating layer of a solar cell module of the present invention. FIG. 10 shows process drawings for illustrating a method for producing the solar cell module shown in FIG. 9.

In each figure to be described below, the same reference numerals are provided for members corresponding to each of those described above, and their detailed description is omitted.

In the embodiment in FIG. 4, the support layer is formed of the substrate 4. Alternatively, for example, as shown in FIG. 7, the support layer is capable of being formed of the substrate 4 and the encapsulating layer 5 (a first encapsulating layer 21, described later). Furthermore, as shown in FIG. 9, the support layer is also capable of being formed of the encapsulating layer 5 (the first encapsulating layer 21, described later) only.

In FIG. 7, the encapsulating layer 5 is provided so that the solar cell elements 3 are embedded in the center in the thickness direction of the encapsulating layer 5. To be more specific, the encapsulating layer 5 is formed so as to cover the entire surfaces (the side surfaces, the top surfaces, and the back surfaces) of the solar cell elements 3.

In the encapsulating layer 5 in FIG. 7, a portion that is positioned at the upper side with respect to the top surfaces of the solar cell elements 3 is defined as the first encapsulating layer 21 that forms the support layer along with the pressure-sensitive adhesive layer 2. A portion that is positioned at the lower side with respect to the top surfaces of the solar cell elements 3 is defined as a second encapsulating layer 22. That is, the first encapsulating layer 21 is formed on the entire back surface of the substrate 4 and the second encapsulating layer 22 is formed on the entire top surface of the back sheet 7.

The first encapsulating layer 21 and the second encapsulating layer 22 are formed of the same material or different materials from each other.

The above-described wavelength conversion material can be also blended into an encapsulating material that forms the first encapsulating layer 21. The mixing ratio of the wavelength conversion material with respect to 100 parts by mass of the polymer is, for example, 0.001 to 10 parts by mass, preferably 0.01 to 5 parts by mass, or more preferably 0.01 to 3 parts by mass.

The support layer formed of the first encapsulating layer 21 and the substrate 4 has an elastic modulus at 25° C. measured in a tensile test of 1 MPa to 9×10³ MPa, or preferably 3 MPa to 9×10³ MPa.

The first encapsulating layer 21 has a thickness of, for example, 10 to 800 μm, or preferably 50 to 500 μm. The boundary between the first encapsulating layer 21 and the second encapsulating layer 22 is shown by a dashed line so as to facilitate understanding thereof. In fact, however, there is no boundary between the first encapsulating layer 21 and the second encapsulating layer 22 and the encapsulating layer 5 is formed by unifying the first encapsulating layer 21 and the second encapsulating layer 22.

In order to obtain the solar cell module 10 shown in FIG. 7, as shown in FIG. 8 (a), first, the protection unit 8 (ref: FIG. 2) is prepared.

Next, as shown in FIG. 8 (b), the first encapsulating layer 21 is laminated on the back surface of the protection unit 8. To be specific, the first encapsulating layer 21 is formed on the entire back surface of the substrate 4.

Next, as shown in FIG. 8 (c), a plurality of the solar cell elements 3 in an aligned state are laminated on the back surface of the first encapsulating layer 21.

Next, as shown in FIG. 8 (d), the second encapsulating layer 22 is disposed on the back surfaces of a plurality of the solar cell elements 3.

Next, as shown in FIG. 8 (e), the back sheet 7 is disposed on the back surface of the second encapsulating layer 22.

Next, as shown in FIG. 8 (f), the obtained laminate is thermocompression bonded.

The first encapsulating layer 21 and the second encapsulating layer 22 are softened and melted by the thermocompression bonding to be unified, so that the encapsulating layer 5 is formed and fills a space between the solar cell elements 3. In this way, a plurality of the solar cell elements 3 are encapsulated.

In this way, the solar cell module 10 shown in FIG. 7 is obtained. The solar cell module 10 shown in FIG. 7 is obtained by allowing the solar cell module 10 shown in FIG. 8 (f) to be reversed upside down.

In the embodiment in FIG. 7, the same function and effect as that in the embodiment in FIG. 4 can be achieved. In addition, the first encapsulating layer 21, along with the substrate 4, forms the support layer, so that the encapsulating properties with respect to the solar cell element 3 are capable of being improved.

In FIG. 9, the first encapsulating layer 21 is defined as the support layer and is disposed in opposed relation to the protective member 6 so as to sandwich the pressure-sensitive adhesive layer 2 between the first encapsulating layer 21 and the protective member 6 in the thickness direction.

The first encapsulating layer 21 has an elastic modulus at 25° C. measured in a tensile test of 1 MPa to 9×10³ MPa, or preferably 3 MPa to 9×10³ MPa.

In order to obtain the solar cell module 10 shown in FIG. 9, for example, first, as shown in FIGS. 10 (a) to 10 (c), the protection unit 8 is prepared.

The protection unit 8 shown in FIG. 10 (c) includes the protective member 6, the pressure-sensitive adhesive layer 2 that is attached to the back surface thereof, and the first encapsulating layer 21 that is formed on the back surface thereof.

In order to prepare the protection unit 8, first, as shown in FIG. 10 (a), the protective member 6 is prepared and next, as shown in FIG. 10 (b), the pressure-sensitive adhesive layer 2 is attached to the back surface of the protective member 6.

In order to attach the pressure-sensitive adhesive layer 2 to the back surface of the protective member 6, as shown in FIG. 1, in the pressure-sensitive adhesive layer 2 on which the substrate 4 is laminated, the surface (the top surface) on which the substrate 4 is not laminated is attached to the back surface of the protective member 6 and thereafter, the substrate 4 is peeled from the pressure-sensitive adhesive layer 2.

Thereafter, as shown in FIG. 10 (c), the first encapsulating layer 21 is formed on the top surface of the pressure-sensitive adhesive layer 2.

In this way, the protection unit 8 in which the first encapsulating layer 21 is laminated on the top surface of the pressure-sensitive adhesive layer 2 is prepared.

Next, in this method, as shown in FIG. 10 (d), a plurality of the solar cell elements 3 in an aligned state are laminated on the back surface of the first encapsulating layer 21.

Next, as shown in FIG. 10 (e), the second encapsulating layer 22 is disposed on the back surfaces of a plurality of the solar cell elements 3.

Next, as shown in FIG. 10 (f), the back sheet 7 is disposed on the back surface of the second encapsulating layer 22.

Next, as shown in FIG. 10 (e), the obtained laminate is thermocompression bonded.

Thereafter, the solar cell module 10 shown in FIG. 9 is obtained. The solar cell module 10 shown in FIG. 9 is obtained by allowing the solar cell module 10 shown in FIG. 10 (e) to be reversed upside down.

In the embodiment in FIG. 9, the first encapsulating layer 21 is provided instead of the substrate 4 in the embodiment in FIG. 4. Thus, when a wavelength conversion material is contained in the pressure-sensitive adhesive layer 2, after allowing light to pass through the pressure-sensitive adhesive layer 2, the wavelength of the light (sunlight) is capable of being converted before the light is absorbed by the first encapsulating layer 21.

That is, before the light is absorbed by the first encapsulating layer 21, the pressure-sensitive adhesive layer 2 is capable of efficiently performing wavelength conversion of light from light in short wavelength (for example, light having a wavelength of less than 350 nm) that is relatively easily absorbed by the first encapsulating layer 21 to light in long wavelength (for example, light having a wavelength of 350 nm or more) that is relatively not easily absorbed by the first encapsulating layer 21.

Thus, thereafter, even when the light in which the wavelength thereof is converted passes through the first encapsulating layer 21, the light is less susceptible to absorption by the first encapsulating layer 21 and in the solar cell element 3, the light in which the wavelength thereof is converted is capable of being efficiently photoelectrically converted, so that the photoelectric conversion efficiency of the solar cell module 10 is capable of being improved.

Furthermore, in the embodiment in FIG. 9, the encapsulating properties with respect to the solar cell element 3 are capable of being improved by the first encapsulating layer 21.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The protection unit of the present invention is used in a solar cell module.

1. A solar cell module comprising:
a solar cell element,
a protective member disposed at one side in a thickness direction of the solar cell element,
a pressure-sensitive adhesive layer interposed between the solar cell element and the protective member and attached to the protective member, and
a support layer formed on the other surface in the thickness direction of the pressure-sensitive adhesive layer and having an elastic modulus at 25° C. measured in a tensile test of 1 MPa to 9×10³ MPa.

2. The solar cell module according to claim 1, wherein
the support layer is an encapsulating layer that encapsulates the solar cell element and/or a substrate that is formed on the one surface in the thickness direction of the pressure-sensitive adhesive layer.

3. The solar cell module according to claim 1, wherein
the pressure-sensitive adhesive layer and/or the support layer contain(s) a wavelength conversion material.

4. The solar cell module according to claim 3, wherein
the wavelength conversion material is an organic dye.

5. A protection unit comprising:
a protective member, a pressure-sensitive adhesive layer, and a support layer used in a solar cell module, wherein
the protective member is disposed at one side in a thickness direction of a solar cell element,
a pressure-sensitive adhesive member is interposed between the solar cell element and the protective member and is attached to the protective member, and
the support layer is formed at the other surface in the thickness direction of the pressure-sensitive adhesive layer and has an elastic modulus at 25° C. measured in a tensile test of 1 MPa to 9×10³ MPa.

6. A pressure-sensitive adhesive sheet comprising:
a pressure-sensitive adhesive layer and a support layer used in a solar cell module, wherein
a pressure-sensitive adhesive member is interposed between a solar cell element and a protective member and is attached to the protective member and
the support layer is formed at the other surface in a thickness direction of the pressure-sensitive adhesive layer and has an elastic modulus at 25° C. measured in a tensile test of 1 MPa to 9×10³ MPa.

7. The pressure-sensitive adhesive sheet according to claim 6, wherein
the pressure-sensitive adhesive layer contains a polymer and a wavelength conversion material.

8. The pressure-sensitive adhesive sheet according to claim 7, wherein
the mixing ratio of the wavelength conversion material with respect to 100 parts by mass of a pressure-sensitive adhesive is 0.001 to 3 parts by mass.

9. The pressure-sensitive adhesive sheet according to claim 6, wherein
the peel pressure-sensitive adhesive force at 180 degrees of the pressure-sensitive adhesive layer with respect to a stainless steel board at 25° C. is 0.1 N/20 mm to 100 N/20 mm.
